(19) United States
(12) Patent Application Publication
(10) Pub. No.: US 2017/0263325 A1
(43) Pub. Date: Sep. 14, 2017

(54) SEMICONDUCTOR MEMORY DEVICE

(71) Applicant: KABUSHIKI KAISHA TOSHIBA, Tokyo (JP)

(72) Inventors: Yoshihiko KAMATA, Yokohama Kanagawa (JP); Mario SAKO, Yokohama Kanagawa (JP); Naofumi ABIKO, Kawasaki Kanagawa (JP); Toshifumi WATANABE, Yokohama Kanagawa (JP)

(73) Assignee: KABUSHIKI KAISHA TOSHIBA, Tokyo (JP)

(21) Appl. No.: 15/261,487

(22) Filed: Sep. 9, 2016

(30) Foreign Application Priority Data
Mar. 14, 2016 (JP) 2016-050117

(51) Int. Cl. G11C 16/28; G11C 16/08; G11C 16/24; G11C 16/04; H01L 27/115

(52) U.S. Cl. CPC G11C 16/28; G11C 16/04; H01L 27/115; G11C 16/24; G11C 16/08

(57) ABSTRACT

According to one embodiment, a semiconductor memory device includes a first transistor which includes a first end coupled to a first node, a second end, and a gate coupled to the second end. A second transistor includes a third end coupled to the first node, a fourth end, and a gate coupled to the fourth end. A third transistor is provided between a first bit line and a second node in a first sense amplifier. A selector is configured to supply a gate of the third transistor with one of a potential of the second end and a potential of the fourth end.

### CROSS-REFERENCE TO RELATED APPLICATIONS

This application is based upon and claims the benefit of priority from Japanese Patent Application No. 2016-050117, filed Mar. 14, 2016, the entire contents of which are incorporated herein by reference.

### FIELD

Embodiments described herein relate generally to a semiconductor memory device.

### BACKGROUND

Semiconductor memory devices are desired to operate with a smaller current consumption.

### BRIEF DESCRIPTION OF THE DRAWINGS

FIG. 1 illustrates functional blocks of a semiconductor memory device of a first embodiment;

FIG. 2 illustrates an example of a block of the first embodiment;

FIG. 3 illustrates an example of components and connections of a sense amplifier of the first embodiment;

FIG. 4 illustrates a view of structures of transistors of the first embodiment when seen from above;

FIG. 5 illustrates the cross-section along V-V line of FIG. 4;

FIG. 6 illustrates components and connections of a BLS controller of the first embodiment;

FIG. 7 illustrates a view of a part of the structure of the memory device of the first embodiment when seen from above;

FIG. 8 illustrate the cross-section along VIII-VIII line of FIG. 7;

FIG. 9 illustrates a state during manufacturing of a part of the memory device of the first embodiment;

FIG. 10 illustrates a state subsequent to FIG. 9;

FIG. 11 illustrates an example of components and connections of the sense amplifier of a second embodiment;

FIG. 12 illustrates potentials of some nodes during a read in the sense amplifier of the second embodiment over time;

FIG. 13 illustrates components and connections of a BLS controller of the second embodiment; and

FIG. 14 illustrates components and connections of a BLS controller of a third embodiment.

### DETAILED DESCRIPTION

In general, according to one embodiment, a semiconductor memory device includes a first transistor which includes a first end coupled to a first node, a second end, and a gate coupled to the second end. A second transistor includes a third end coupled to the first node, a fourth end, and a gate coupled to the fourth end. A third transistor is provided between a first bit line and a second node in a first sense amplifier. A selector is configured to supply a gate of the third transistor with one of a potential of the second end and a potential of the fourth end.

Embodiments will now be described with reference to the figures. In the following description, components with substantially the same functionalities and configurations will be referred to with the same reference numerals, and repeated descriptions may be omitted. Moreover, all descriptions for a particular embodiment are applicable as descriptions of another embodiment, unless explicitly or obviously denied. Each embodiment illustrates the device and method for materializing the technical idea of that embodiment, and the technical idea of an embodiment does not specify the quality of the material, shape, structure, arrangement of components, etc. to the following.

### First Embodiment

(Configuration)

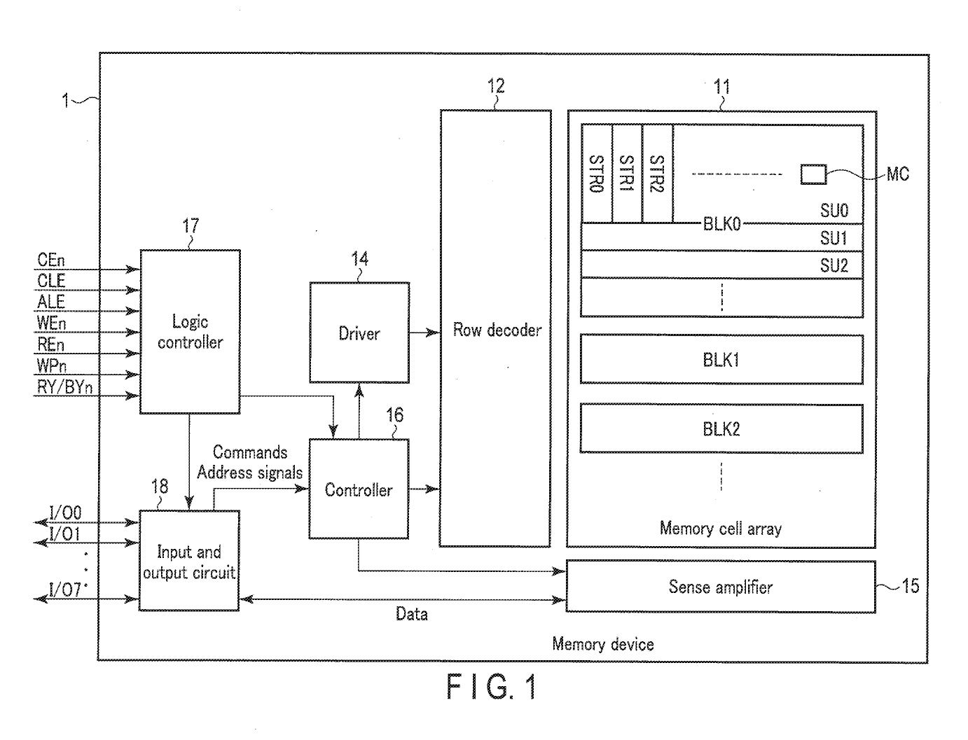

FIG. 1 illustrates functional blocks of a semiconductor memory device 1 of the first embodiment. As illustrated in FIG. 1, the memory device 1 includes a memory cell array 11, a row decoder 12, a driver 14, sense amplifier 15, a controller 16, a logic controller 17, and an input and output circuit 18.

The memory cell array 11 includes plural memory cells MC. The memory cell array 11 and the memory cells MC can have any configuration. For example, as illustrated in FIG. 1, the memory cell array 11 includes blocks BLK, each of which includes strings units SU, each of which includes plural NAND strings STR, each of which includes plural memory cells MC. Each memory cell MC has an insulator, for example, and stores data based on the quantity of electrons in the insulator in a nonvolatile manner. The memory cells MC are coupled to interconnects, such as word lines, bit lines, and a source line. The memory cell MC may be arranged in three dimensions.

The input and output circuit 18 transmits and receives signals I/O0 to I/O7 to and from outside the memory device 1. The signal I/O has a width of, for example, eight bits, is the substance of data and includes commands, write data or read data, and address signals, etc.

The logic controller 17 receives various control signals from outside the memory device 1, and controls the controller 16 and the input and output circuit 18 based on the control signals. The control signals include signals CEn, CLE, ALE, WEn, REn, WPn, and RY/BYn, for example. The “n” at the end of the name of a signal represents that the signal is asserted when it is at the low level.

An asserted signal CEn enables the memory device 1. Asserted signals CLE and ALE notify the memory device 1 that the signal I/O flowing into the memory device 1 in parallel to the asserted signals CLE and ALE are a command and an address, respectively. An asserted signal WEn instructs memory device 1 to take in the signal I/O flowing into the memory device 1 in parallel to the asserted signal WEn. An asserted signal REn instructs the memory device 1 to output the signal I/O. An asserted signal WPn instructs the memory device 1 to refrain from performing a data write and erasure. The signal RY/BYn indicates whether the memory device 1 is in a ready state, in which the memory device 1 accepts instructions from outside, or is in a busy state, in which the memory device 1 does not accept instructions from outside, and indicates the busy state with the low level.

The controller 16 controls operations of the row decoder 12, the driver 14, and the sense amplifier 15 based on the commands and the address signals.

The row decoder 12 selects one block BLK based on the address signal. The driver 14 supplies various potentials to a block BLK selected by the row decoder 12 via the row decoder 12.

The sense amplifier 15 senses data read from the memory cell array 11. The sensed data is output from the memory device 1 via the input and output circuit 18 as read data. The sense amplifier 15 also receives from the input and output circuit 18 write data received by the input and output circuit 18 from outside the memory device 1, and transfers the write data to the memory cell array 11.

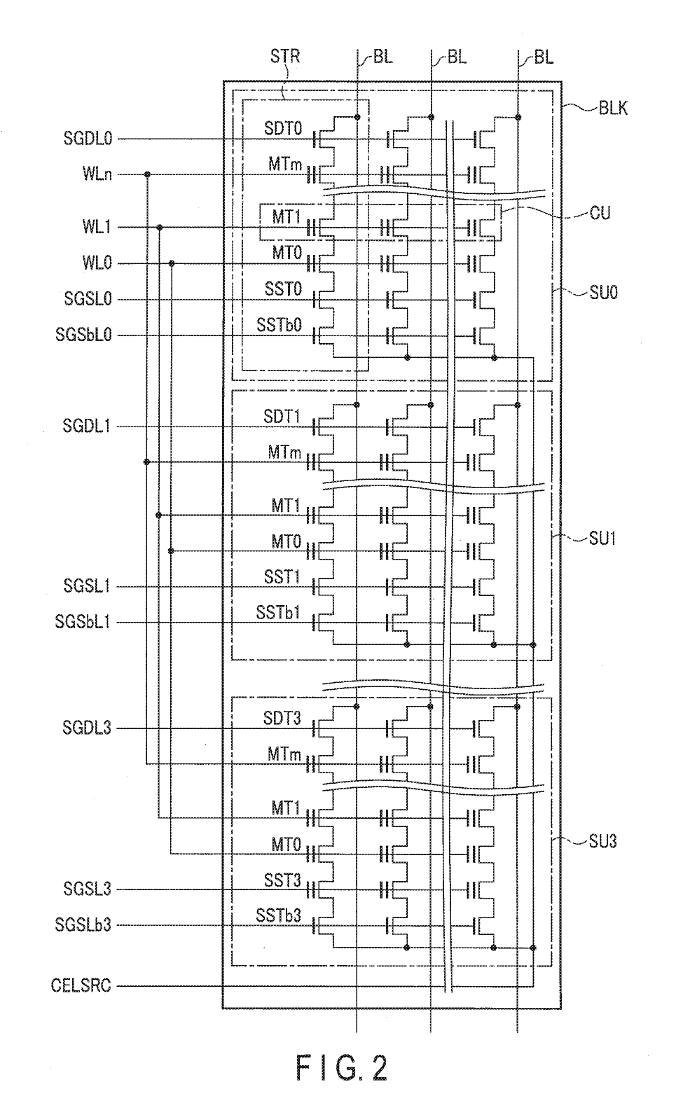

Each block BLK has components and connections illustrated, for example, in FIG. 2. FIG. 2 is based on an example in which each block BLK includes plural string units SU, and each string unit SU includes plural strings STR.

In each block BLK, one bit line BL is coupled to plural strings STR. Strings STR respectively coupled to different bit lines BL on a one-to-one basis make one string unit SU. Each block BLK includes string units SU0 to SUk, where k is a natural number and is three as an example in the following description.

Each string STR includes a select gate transistor SSTb (SSTb0, SSTb1, SSTb2, or SSTb3), a select gate transistor SST (SST0, SST1, SST2, or SST3), memory cell transistors MT0 to MTm, and a select gate transistor SDT (SDT0, SDT1, SDT2, or SDT3). The transistors SSTb, SST, and MT and SDT are coupled in series in this order between a cell source line CELSRC and one bit line BL.

Select gate transistors SDTq, SSTq, and SSTbq (q being one of zero and a natural number not greater than k (=3)) belong to a string unit SUq.

In each string unit SU, for each of the cases of p (p being 0 to m), gates of cell transistors MTp are coupled to a word line WLp. The cell transistors MT sharing a word line WL in one string unit SU make a cell unit CU. Furthermore, in each block BLK, the word lines WLp in different string units SU are also coupled to each other.

For each of the cases of q (q being 0 to 3, respective gates of respective select gate transistors SDTq of strings STR of a string unit SUq are coupled to a select gate line SGDLq. For each of the cases of q (q being 0 to 3, respective gates of respective select gate transistors SSTq of strings STR of a string unit SUq are coupled to a select gate line SGSLq. For each of the cases of q (q being 0 to 3, respective gates of respective select gate transistors SSTbq of strings STR of a string unit SUq are coupled to a select gate line SGSbLq.

Two or more select gate lines SGSL of the string units SU in one block BLK may be coupled to each other. Moreover, two or more select gate lines SGSbL of the strings units SU in one block may be coupled to each other.

The configuration of the cell array 11 is disclosed in the U.S. Patent Application Publication No. 2009/0267128 titled “three-dimensional lamination nonvolatile semiconductor memory.” Other examples are disclosed in the U.S. Patent Application Publication No. 2009/0268522 titled “three-dimensional lamination nonvolatile semiconductor memory”, the U.S. Patent Application Publication No. 2010/0207195 titled “non-volatile semiconductor storage device and method of manufacturing the same”, and the U.S. Patent Application Publication No. 2011/0284946 titled “semiconductor memory and method for manufacturing same”. The entire contents of these patent applications are incorporated by reference in the specification of the present application.

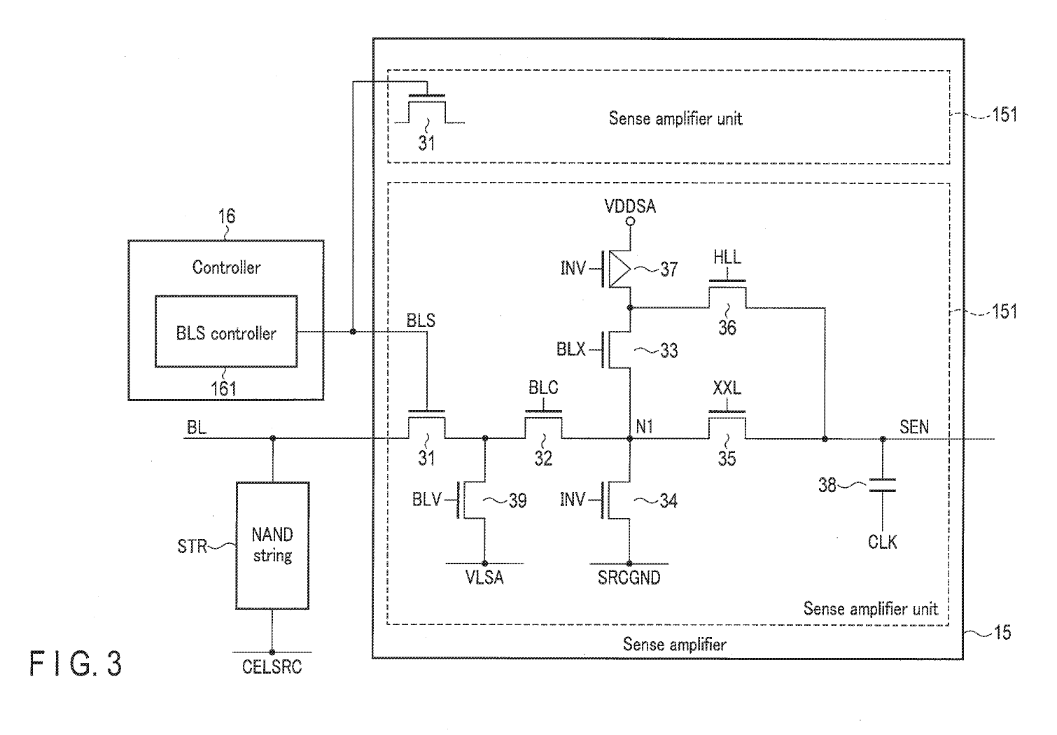

Referring to FIG. 3, the sense amplifier 15 will now be described. FIG. 3 illustrates an example of components and connections of the sense amplifier 15 of the memory device 1 of the first embodiment. The sense amplifier 15 includes plural sense amplifier units 151. Each sense amplifier unit 151 has the same set of components and connections. Each sense amplifier unit 151 is coupled to one bit line BL.

As illustrated in FIG. 3, each sense amplifier unit 151 includes n-type metal oxide semiconductor field effect transistors (MOSFETs) 31 to 36 and 39, a p-type MOSFET 37, and a capacitor element 38.

The transistor 31 has a high withstand-voltage and receives a signal BLS at its gate. The signal BLS is supplied from a BLS controller 161. The BLS controller 161 is included in the controller 16, for example. The BLS controller 161 supplies the signal BLS to the gates of respective transistors 31 of all the sense amplifier units 151. The transistor 31 is coupled at one end to one bit line BL corresponding to the sense amplifier unit 151 which includes that transistor 31.

The transistor 39 is coupled between the other end of the transistor 31 and a node VLSA, and receives at its gate a signal BLV from the controller 16. The transistor 32 is coupled between the other end of the transistor 31 and a node N1, and receives at its gate a signal BLC from the controller 16. The transistor 33 is coupled between the node N1 and one end of the transistor 37, and receives at its gate a signal BLX from the controller 16. The transistor 37 is coupled at the other end to a node of a power potential VDDSA, and receives at its gate a signal INV. The signal INV is a potential on a node in a latch coupled to the sense amplifier unit 151. The node N1 is also coupled to a node of a ground potential SRCGND via the transistor 34. The transistor 34 receives at its gate the signal INV.

The node N1 is also coupled to a node SEN via the transistor 35. The transistor 35 receives at its gate a signal XXL from the controller 16. The node SEN is a node reflecting a potential of data stored by a read-target memory cell transistor MT, and is coupled to, for example, a data latch (not shown) via a transistor (not shown).

The node SEN is also coupled to a node to which the transistors 33 and 37 are coupled via the transistor 36. The transistor 36 receives a signal HLL from the controller 16. The node SEN further receives a signal CLK from the controller 16 via the capacitor element 38.

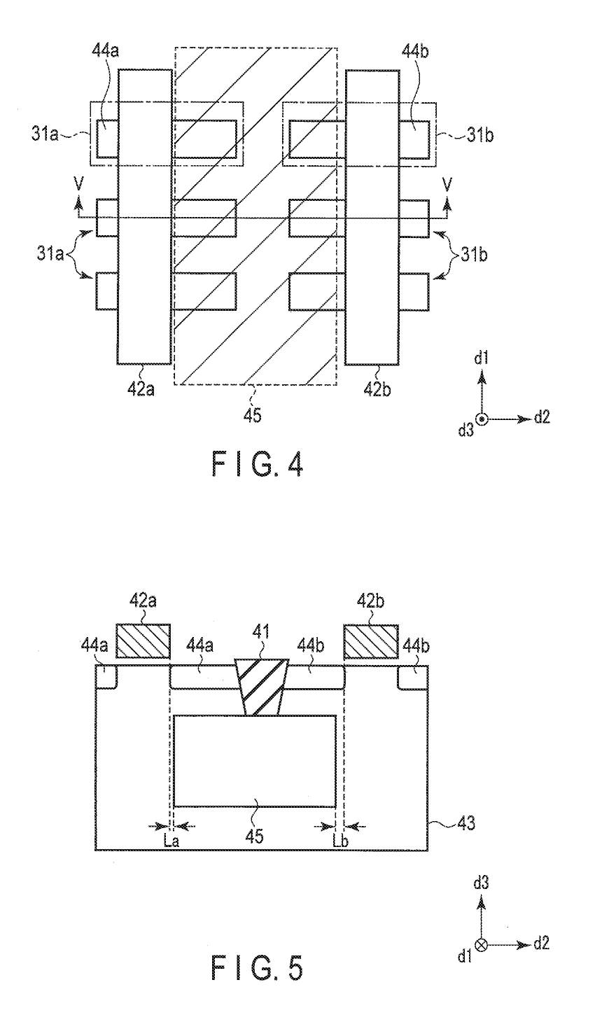

Referring to FIG. 4, the structures of the transistors 31 will now be described. FIG. 4 illustrates a view of the structures of the transistors 31 of the memory device 1 of the first embodiment when seen from above. FIG. 5 illustrates the cross-section along line V-V of FIG. 4. As described above, the memory device 1 includes plural transistors 31.

As illustrated in FIGS. 4 and 5, the transistors 31 include transistors 31a and 31b. The transistors 31a are included in sense amplifier units 151 coupled to bit lines BL with even addresses, for example. The transistors 31b are included in sense amplifier units 151 coupled to bit lines BL with odd addresses, for example. The transistors 31a line up along a d1-axis, and the transistors 31b also line up along the d1-axis. The set of the transistors 31a. and the set of the transistors 31b line up along a d2-axis on both sides of an insulator 41 for isolation. The d1-axis and d2 axis cross at a right angle. The insulator 41 has a shallow trench isolation (STI) structure, for example.

The transistors 31a share a gate electrode 42a. The gate electrode 42a extends along the d1-axis, and is located above, along a d3-axis, a p-type substrate (or to well) 43. The d3-axis crosses d1-axis and d2-axis at right angles. Each transistor 31a includes a pair of source/drain areas 44a. Source/drain areas 44a of a pair sandwich an area under the gate electrode 42a where a channel is formed, i.e., a channel region, in an area of the surface of the substrate 43.

The transistors 31b share a gate electrode 42b. The gate electrode 42b extends along the d1-axis, and is located above, along the d3-axis, the substrate 43. Each transistor 31b includes a pair of source/drain areas 44b. Source/drain areas 44b of a pair sandwich a channel region under the gate electrode 42b in an area of the surface of the substrate 43.

The substrate 43 includes an impurity region 45 under, along the d3-axis, the insulator 41. The impurities in the impurity region 45 have the same conductivity type as that of the substrate 43, have the same conductivity type as that of the channel regions of the transistors 31a and 31b, and are of the p-type in the ongoing example. The impurity region 45 is provided, for example, in order to prevent a channel from being formed under the insulator 41, and is referred to as a channel stopper, etc.

The transistors 31a and 31b are desired to have substantially the same threshold voltage. However, either of a threshold voltage Vtha of the transistors 31a and a threshold voltage Vthb of the transistors 31b is higher than the other. The following description is based on an example where the threshold voltage Vtha is higher than the threshold voltage Vthb. The different threshold voltages result from the impurity region 45. The details are as follows.

The impurity region 45 has a distance La with the gate electrode 42a (or, an extension of an end of the gate electrode 42a), and has a distance Lb with the gate electrode 42b (or, an extension of an end of the gate electrode 42a). The center of the impurity region 45 is shifted from the center of a line connecting the end of the gate electrode 42a and the end of the gate electrode 42b. For this reason, the distances La and Lb differ from each other. FIGS. 4 and 5 illustrate an example where the distance La is shorter than the distance Lb. The reason for the difference in distances La and Lb results from a manufacturing method, and will be described later.

The distance La is shorter than the distance Lb, and therefore the impurities in the impurity region 45 diffuse more easily into the channel regions of the transistor 31b than into the channel regions of the transistors 31a. This diffusion makes the p-type impurity concentration of the channel regions of the transistors 31a higher than that of the transistors 31b. As a result, the threshold voltage Vtha of the transistors 31a is higher than the threshold voltage Vthb of the transistors 31b.

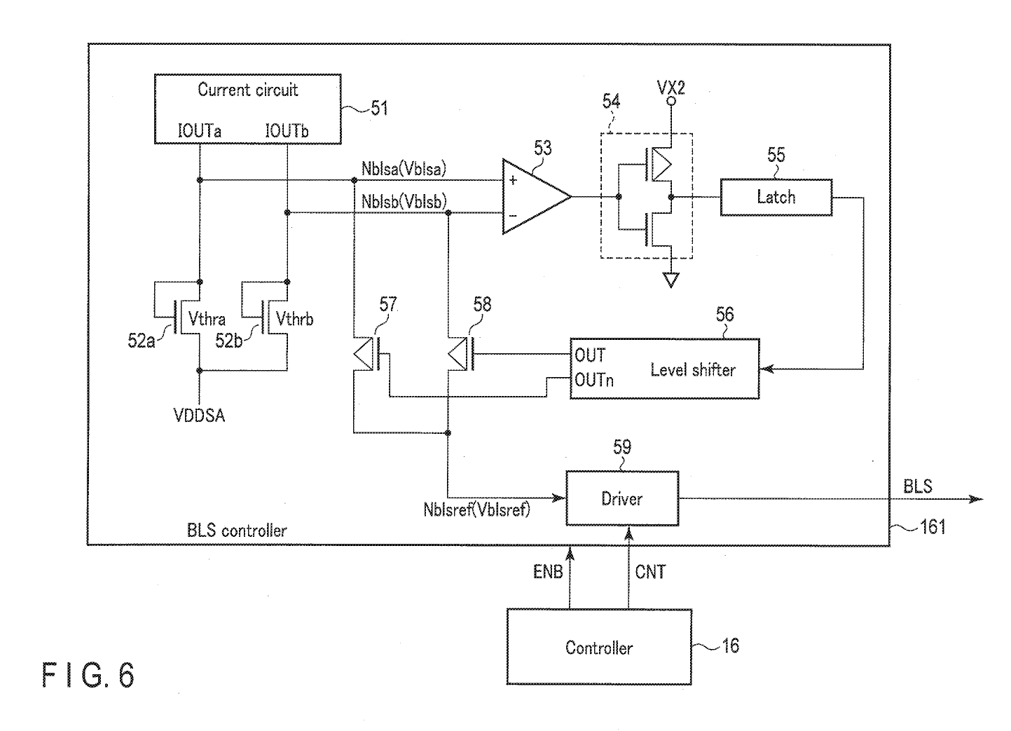

Referring to FIG. 6, the BLS controller 161 will now be described. FIG. 6 illustrates components and connections of the BLS controller 161 of the memory device 1 of the first embodiment. The BLS controller 161 includes a current circuit 51, replica transistors 52a. and 52b, an operational amplifier 53, a converter 54, a data latch 55, a level shifter 56, p-type MOSFETs 57 and 58, and a driver 59.

The BLS controller 161 is enabled while receiving an asserted signal ENB from the controller 16. The current circuit 51 has two outputs, IOUTa and IOUTb. The current circuit 51 outputs substantially the same currents from an output IOUTa and an output IOUTb. The current circuit 51 is based, for example, on a current mirror circuit.

A node Nblsa of the output IOUTa is coupled to one end and a gate of the transistor 52a. The other end of the transistor 52a is coupled to a node of a potential VDDSA. A node Nblsb of the output IOUTb is coupled to one end and a gate of the transistor 52b. The other end of the transistor 52b. is coupled to the node of the potential VDDSA.

The transistor 52a has a threshold voltage Vthra substantially the same as the threshold voltage Vtha of the transistors 31a, and the transistor 52b has a threshold voltage Vthrb substantially the same as the threshold voltage Vthb of the transistors 31b. To this end, the transistors 52a and 52b can have features substantially the same as the transistors 31a and 31b, respectively. “Substantially the same” herein refers to that equivalence is intended. For example, that the transistors 52a and 52b have substantially the same features refers to that they are provided in an attempt to make them have substantially the same features as the transistors 31a and 31b. To this end, the transistors 52a and 52b are provided as replicas of the transistors 31a and 31b, respectively, and, for example, are formed in parallel with the transistors 31a and 31b through a set of manufacturing steps.

Two or more transistors 52a may be provided, and two or more transistors 52b may be provided. In this case, the plural transistor 52a are coupled in parallel, and the plural transistor 52b are coupled in parallel. This can avoid variations in characteristics of transistors 52a and produce the same state as that where one transistor 52a with average characteristics were used. The same holds true for the transistors 52b.

The nodes Nblsa and Nblsb are further coupled to a non-inverting input and an inverting input of the operational amplifier 53, respectively. An output of the operational amplifier 53 is coupled to an input of the converter 54. The converter 54 converts the output of the operational amplifier 53 into a digital signal. The converter 54 is, for example, an inverter circuit, outputs an input smaller than a particular reference as the low level digital signal, and outputs an input larger than the reference as the high level digital signal.

The output of the converter 54 is coupled to an input of the latch 55. The latch 55 is, for example, a D-type latch circuit, and stores and keeps outputting the signal received at its input. An output of the latch 55 is supplied to the level shifter 56.

While the level shifter 56 is receiving the low level-signal at its input, it outputs as its output OUT a high potential of a magnitude which cuts off the transistors 57 and 58, and outputs the ground potential VSS (=0V) from its output OUTn. In contrast, while the level shifter 56 is receiving the high-level signal, it outputs as its output OUTn a high potential of a magnitude which cuts off the transistors 57 and 58, and outputs the ground potential from its output OUT. The output OUT is coupled to a gate the transistor 58. The output OUTn is coupled to a gate of the transistor 57.

One end of the transistor 57 is coupled to the Node Nblsa, and one end of the transistor 58 is coupled to the Node Nblsb. The other end of each of the transistors 57 and 58 is coupled to each other at a node Nblsref, and coupled to an input of the driver 59. The driver 59 outputs a potential received at its input as the signal BLS at a timing based on the signal CNT. The signal CNT is supplied, for example, from the controller 16.

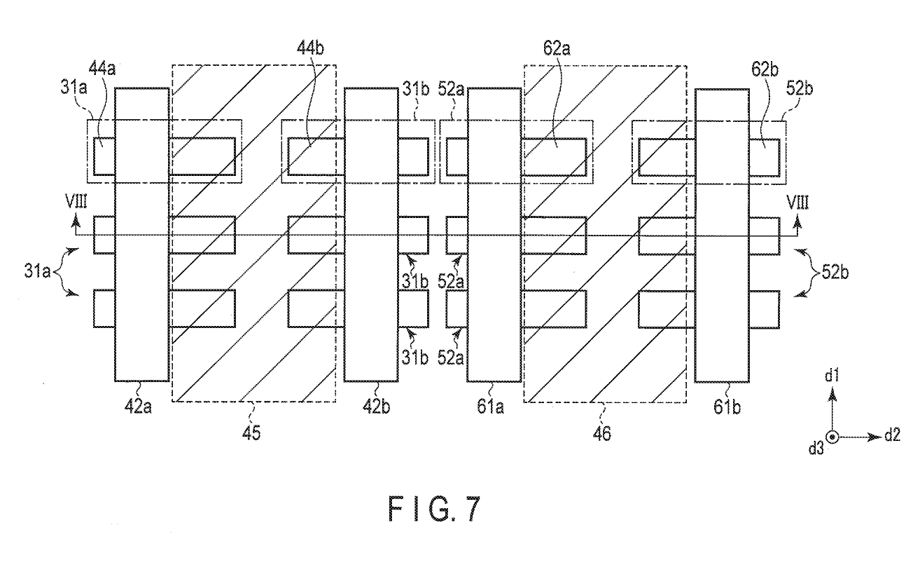

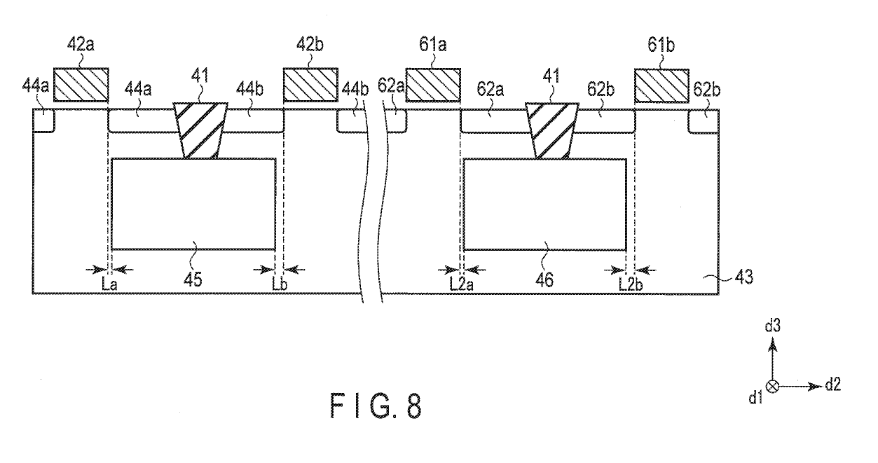

Referring to FIGS. 7 and 8, the structures of the replica transistors 52a and 52b will be now described. FIG. 7 illustrates a view of a part of the structure of the memory device 1 of the first embodiment when seen from above. FIG. 8 illustrates the cross-section along line VIII-VIII of FIG. 7. As described above, the transistors 52a and 52b are provided in an attempt to make them have substantially the same characteristics as the transistors 31a and 31b. To this end, as illustrated in FIG. 8, the transistors 52a and 52b have substantially the same structures as the transistors 31a and 31b, respectively.

As illustrated in FIGS. 7 and 8, the transistors 52a line up along the d1-axis, and the transistors 52b also line up along the d1-axis. The set of the transistors 52a and the set of the transistors 52b line up along the d2-axis on either side of the insulator 41.

The transistors 52a share a gate electrode 61a. The gate electrode 61a extends along the d1-axis, and is located above, along the d3-axis, the substrate 43. Each transistor 52a includes one pair of source/drain areas 62a. Source/drain areas 62a of a pair sandwich a channel region below e gate electrode 61a in an area of the surface of the substrate 43.

The transistors 52b share a gate electrode 61b. The gate electrode 61b extends along the d1-axis, and is located above, along the d3-axis, the substrate 43. Each transistor 52b includes one pair of source/drain areas 62b. Source/drain areas 62b of a pair sandwich a channel region below the gate electrode 61b in an area of the surface of the substrate 43.

The substrate 43 includes an impurity region 46 below, along the d3-axis, the insulator 41 between the gate electrodes 61a and 61b.

The gate electrodes 61a and 61b, the source/drain areas 62a and 62b, and the impurity region 46 have respective dimensions substantially the same as the gate electrodes 42a and 42b, the source/drain areas 44a and 44b, and the impurity region 45, respectively. Moreover, the positional relationships (or, distances) among the gate electrodes 61a and 61b, the source/drain areas 62a and 62b, and the impurity region 46 are substantially the same as the positional relationships (or, distances) among the gate electrodes 42a and 42b, the source/drain areas 44a and 44b, and the impurity region 45, respectively. For this reason, a distance L2a between the impurity region 46 (or, an end thereof) and the gate electrode 61a (or, an extension of an end of the gate electrode 61a) is substantially the same as the distance La. A distance L2b between the impurity region 46 and the gate electrode 61b (or, extension of an end of the gate electrode 42a) is substantially the same as the distance Lb.

(Manufacturing Process)

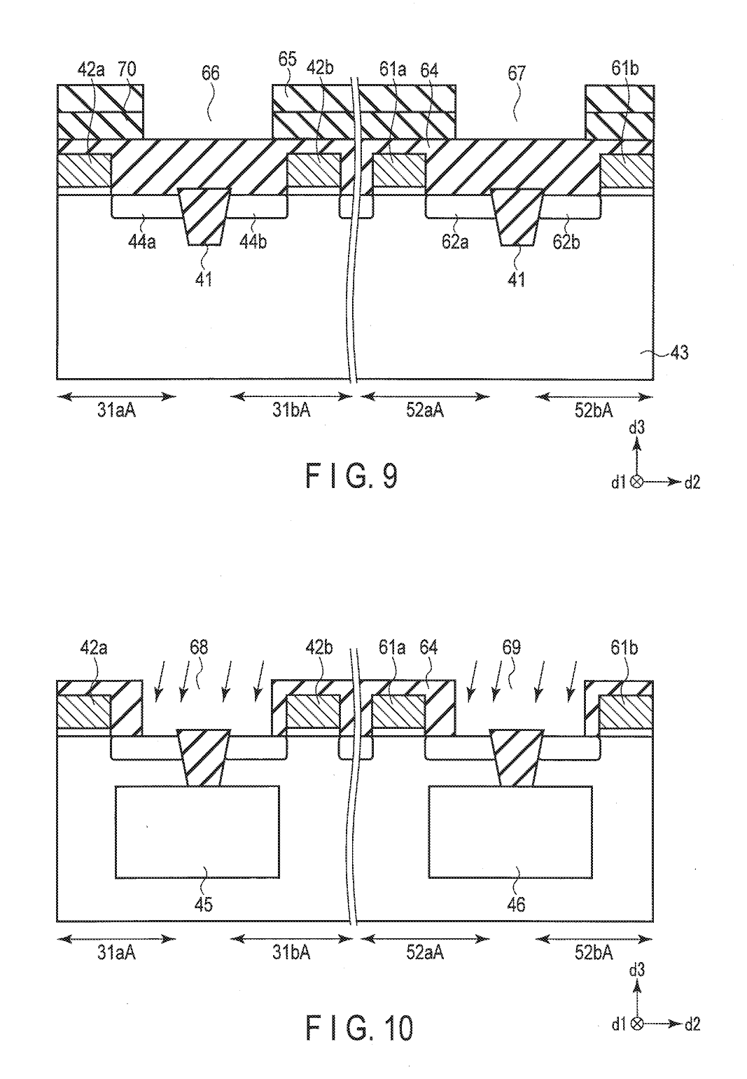

Referring to FIGS. 9 and 10, a method of manufacturing the transistors 31a and 31b and the transistors 52a and 52b will now be described. FIG. 9 illustrates one state during manufacturing of a part of the memory device 1 of the first embodiment. FIG. 10 illustrates a state subsequent to FIG. 9. Areas 31aA, 31bA, 52aA, and 52bA are where the transistors 31a, 31b, 52a, and 52b will be formed, respectively.

The transistors 31a, 31b, 52a, and 52b include substantially identical features of substantially they same material and have substantially the same dimensions. To this end, for example, the transistors 31a, 31b, 52a and 52b are formed in parallel. The transistors 31a, 31b, 52a, and 52b can be formed by any method, as long as they are formed in parallel so that the transistors 31a and 52a. have substantially the same characteristics and the transistors 31b and 52b have substantially the same characteristics. An example will be described in the following.

First, the insulator 41 is formed in an area of the surface of the substrate 43. The gate electrodes 42a, 42b, 61a, and 61b are then formed above the substrate 43. The gate electrodes 61a and 61b are included in the transistors 52a and 52b, respectively. Then, ion implantation with the gate electrodes 42a, 42b, 61a, and 61b as masks forms the source/drain areas 44a, 44b, 62a, and 62b, for example. Insulators may then be formed on side walls of the gate electrodes 42a, 42b, 61a, and 61b, or high-concentration source/drain areas may be formed.

A hard mask 64 and a photoresist 70 are then formed on the whole surface of the structure obtained by the steps so far, for example. A mask 65 is formed on the photoresist 70. The mask 65 has an opening 66 between the gate electrodes 42a and 42b, and has an opening 67 between the gate electrodes 61a and 61b. The mask 65 is intended to have the opening 66 at exactly the middle between the gate electrodes 42a and 42b and the opening 67 at exactly the middle between the gate electrodes 61a and 61b. However, in actuality, misalignment results in the positions of the openings 66 and 67 shifted in either direction along the d2-axis. FIG. 9 illustrates an example where the openings 66 and 67 are shifted rightward from the intended positions. The quantity of the shift of the opening 67 is the same as that of the opening 66. The openings 66 and 67 of the mask. 65 are then transferred to the photoresist 70 by photolithography and anisotropic etching with the mask 65.

As illustrated in FIG. 10, the openings of the photoresist 70 (not shown) are transferred to the hard mask 64 by additional anisotropic etching. This makes openings 68 and 69 in the hard mask 64. The openings 68 and 69 are located under the openings of the photoresist 70, and are therefore located under where the openings 66 and 67 of the mask 65 were. Therefore, the openings 68 and 69 are also shifted rightward along the d2-axis from the intended positions as are the openings 66 and 67. For this reason, when based on the ongoing example, the distance between the left end of the opening 68 and the gate electrode 42a is longer than the distance between the right end of the opening 68 and the gate electrode 42b. Similarly, the distance between the left end of the opening 69 and the gate electrode 61a is longer than the distance between the right end of the opening 69 and the gate electrode 61b.

The photoresist 70 is then removed, and then the impurity regions 45 and 46 are formed by ion implantation through the openings 68 and 69. The trajectories of ion beams have an inclination from the d3-axis. Based on the trajectories of ion beams inclining and the openings 68 and 69 shifted toward either direction, the impurity region 45 is asymmetric with respect to the middle between the gate electrodes 42a and. 42b, and the impurity region 46 is asymmetric with respect to the middle between the gate electrodes 61a and 61b. As a result, the distances La and Lb differ and the distances L2a and. L2b differ, as described above.

The hard mask 64 is then removed and the structure of FIG. 8 is obtained.

(Operation)

An operation of the BLS controller 161 illustrated in FIG. 6 will now be described. The controller 16 generates a signal (or, potential) on the node Nblsref when the memory device 1 starts to receive supply of power, for example. To this end, the controller 16 outputs an asserted signal ENB. As a result, the BLS controller 161 starts to operate. With the start, currents of the same particular magnitude flow through the transistors 52a and 52b. The transistors 52a and 52b respectively have different threshold voltages, and therefore a potential Vblsa of the node Nblsa and a potential Vblsb of the node Nblsb have different magnitudes. The potential Vblsa is equal to the sum of the potential VDDSA and the threshold voltage Vthra of the transistor 52a, and the potential. Vblsb is equal to the sum of the potential VDDSA and the threshold voltage Vthrb of the transistor 52b.

A value determined based on the relationship between the magnitudes of the potentials Vblsa and Vblsb is output from the converter 54. Specifically, when the potential Vblsa is higher than the potential Vblsb, a signal of the high level is output from the operational amplifier 53, and a signal of the low level is output from the converter 54. In contrast, when the potential Vblsb is higher than the potential Vblsa, a signal of the low level is output from the operational amplifier 53, and a signal of the high level is output from the converter 54. Once the signal is output from the converter 54, the signal is kept stored by the latch 55. The controller 16 negates the signal ENB after the elapse of a particular time longer than a time for the data to be taken into the latch 55 from, for example, the start of supply of the asserted signal ENB.

The outputs OUT and OUTn based on the output of the latch 55 are output from the level shifter 56. When the output of the latch 55 is at the low level, or the potential Vblsa is higher than the potential Vblsb, the signal OUT of a high potential is output, which turns off the transistor 58, whereas the output OUTn of the ground potential VSA is output, which turns on the transistor 57. As a result, the potential Vblsa is transferred to the node Nblsref.

In contrast, when the potential Vblsb is higher than the potential Vblsa, the signal OUT of the ground potential VSS is output, which turns on the transistor 58, whereas the signal OUTn of a high potential is output, which turns off the transistor 57. As a result, the potential Vblsb is transferred to the node Nblsref.

As described, when the threshold voltage Vthra is higher than the threshold voltage Vthrb, the potential Vblsa (=VDDSA+Vthra) is transferred to the driver 59 via the transistor 57. In contrast, when the threshold voltage Vthrb is higher than the threshold voltage Vthra, the potential Vblsb (=VDDSA+Vthrb) is transferred to the driver. 59 via the transistor 58. In other words, the sum of the higher one of the threshold voltages Vthra and Vthrb and the potential VDDSA is supplied to the driver 59.

The driver 59 receives the asserted signal CNT, and it outputs the potential Vblsref of node Nblsref (=VDDSA+Vthra or VDDSA+Vthrb) as the signal BLS while it is receiving the asserted signal CNT.

(Advantages)

When the transistors 31a and 31b transfer a particular potential, they need to receive at their gates the sum of the to-be-transferred Potential and the threshold voltage Vtha, and the sum of the to-be-transferred potential and the threshold voltage Vthb, respectively. The potential applied at the gates is common to the transistors 31a and 31b. For this reason, in order the magnitude of the Potential which should be applied to the gates of the transistors 31a and 31b to be determined, the threshold voltages Vtha and Vthb of the transistors 31a and 31b are taken into consideration. However, the transistors 31a and 31b laid out as illustrated in FIGS. 4 and 5 may respectively have threshold voltages Vtha and Vthb, which are different due in part to the manufacturing method as described above. It cannot be easily known which of the threshold voltages Vtha and Vthb are higher. Based on this, a potential sufficiently higher than the to-be-transferred potential can be applied to the gates of the transistors 31a and 31b. For example, the transistors 31a and 31b are applied at their gates with a potential much higher than the potential VDDSA even when they only need to transfer a potential lower than the potential vDDSA.

Such an application of a potential high enough to the gates of the transistors 31a and 31b consumes a large current. In light of this, a replica transistor can be used. For example, there are provided diode-coupled first replica transistors with the same characteristics as the transistors 31a, and diode-coupled second replica transistors with the same characteristics as the transistors 31b. The first and second replica transistors are formed in parallel to the transistors 31a and 31b as are the transistors 52a and 52b. The first replica transistors are coupled in parallel, and the second replica transistors are coupled in parallel. Then, the sum of the voltage over the end of the parallel-connection structure of the first replica transistors and the potential VDDSA is applied to the gate of the transistor 31a, and the sum of the voltage over the end of the parallel-connection structure of the second replica transistors and the potential VDDSA is applied to the gate of the transistor 31b. The reason why the parallel-coupled first and second replica transistors are provided is to suppress any variation in the threshold voltages of the first and second replica transistor. It is, however, thought that this method cannot allow one or more of the transistors 31a and 31b to transfer the potential VDDSA, or to fully turn on. The reason for this is that the threshold voltages Vtha and Vthb differ due to misalignment of the mask 65 as described with reference to FIGS. 9 and 10, and, therefore with the same principle as differing threshold voltages Vthra and Vthrb, the threshold voltages of the first and second replica transistors also differ. The voltage over the parallel connection structure of the first replica transistors is equal to the average of the respective threshold voltages of the first replica transistors, and the voltage over the parallel connection structure of the second replica transistors is equal to the average of the respective threshold voltages of the second replica transistors. For this reason, the sum of the average of the threshold voltages of the first replica transistors and the voltage VDDSA is applied to the gate of the transistors 31a, and the sum of the average of the threshold voltages of the second replica transistors and the voltage VDDSA is applied to the gate of the transistors 31b. The average threshold voltages of the first replica transistors and the second replica transistors are lower than the threshold voltage Vtha, which is higher. For this reason, the transistor 31a with the threshold voltage Vtha cannot transfer the potential VDDSA.

According to the memory device 1 of the first embodiment, there are provided the transistors 52a and 52b, which respectively have substantially the same structures and dimensions as the transistors 31a and 31b, which respectively have differing threshold voltages Vtha and Vthb. This allows the transistors 52a and 52b to respectively have the threshold voltages Vthra and Vthrb substantially the same as the transistors 31a and 31b, and therefore the threshold voltage Vthra and Vthrb differ. Each of the transistors 52a and 52b is diode-coupled. For this reason, the potential difference between the end of the transistor 52a is equal to the threshold voltage Vthra, and the potential difference between the end of the transistor 52b is equal to the threshold voltage Vthra. In addition, the sum of the larger one of the voltages of ends of the transistors 52a and 52b and the to-be-transferred potential is a plied to the gates of the transistors 31a and 31b. As a result, the sum of the threshold voltages Vthra or Vthrb, which are respectively substantially the same as the larger one of the threshold voltages Vtha and Vthb, and the potential VDDSA is applied to the gates of the transistors 31a and 31b as the signal BLS. This allows any of the transistors 31a and 31b to transfer the potential VDDSA while it is receiving the signal BLS at its gate, regardless of which of the transistors 31a and 31b has the higher threshold voltage.

Moreover, the potential applied to the gates of the transistor and 31b to allow them to transfer the potential VDDSA is the sum of the threshold voltage Vthra or Vthrb, which substantially is equal to the higher one of the threshold voltages Vtha and Vthb, and the potential VDDSA. For this reason, the potential applied to the gates of the transistors 31a and 31b to allow them to transfer the potential VDDSA is smaller than in the case without replica transistors. This can reduce the current consumed in the memory device 1.

### Second Embodiment

The second embodiment differs from the first embodiment in the sense amplifier 15. The features other than sense amplifier 15 are the same as those of the first embodiment.

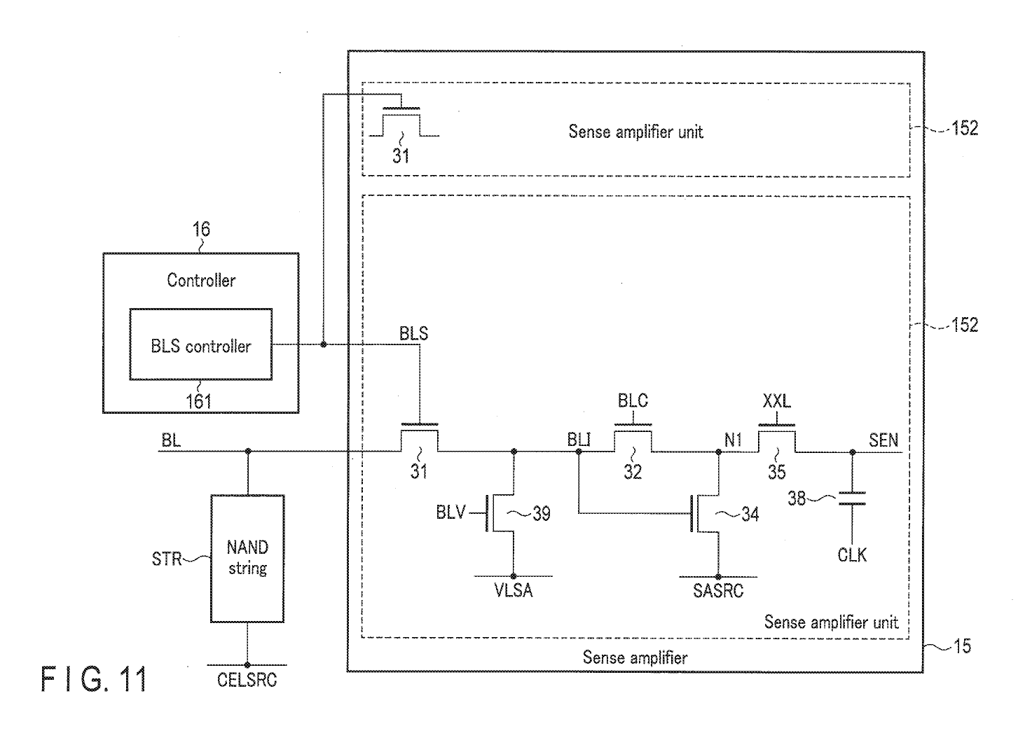

The sense amplifier 15 includes plural sense amplifier units 152 respectively coupled to the bit lines BL as in the first embodiment, and FIG. 11 illustrates components and connections of the sense amplifier unit 152. The sense amplifier units 152 all have the same set of components and connections.

As illustrated in FIG. 11, each sense amplifier unit. 152 includes transistors 31, 32, 34, 35, and 39, and a capacitor element 38. The transistor 34 is coupled between a node N1 and a node SASRC. The potential of the node SASRC is controlled by the controller 16. The transistor 34 is also coupled at its gate to a node BLI between the transistors 31 and 32. The transistor 39 is coupled between the node BLI and a node VLSA. The potential of the node VLSA is controlled, for example by the controller 16. The transistor 39 receives a signal BLV from the controller 19 at its gate. The transistors 33, 36, and 37 of FIG. 3 are not provided.

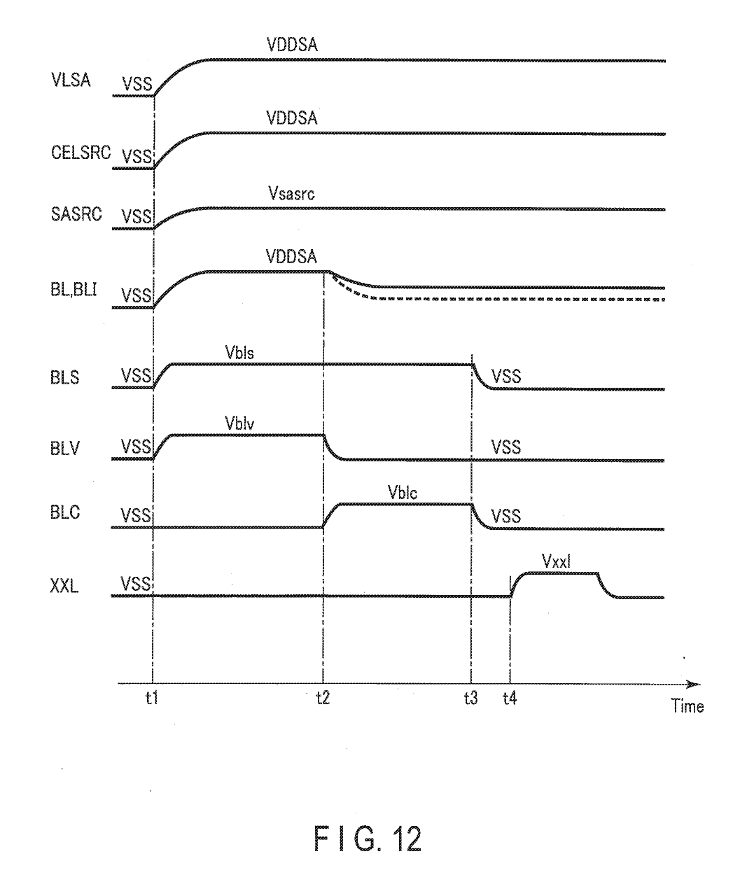

Referring to FIG. 12, an operation of the sense amplifier 15 of FIG. 11 will now be described. FIG. 12 illustrates potentials of some nodes during a read by a sense amplifier unit 152 of the memory device 1 of the second embodiment over time. As illustrated in FIG. 12, all illustrated nodes (or, interconnects) have the ground potential VSS at the start of the operation of FIG. 12. Furthermore, a string STR including a cell transistor MT selected for the read is coupled to a bit line BL at the start of the operation, and the selected cell transistor MT is applied with a read voltage at its gate. Bv application of the read voltage, the selected cell transistor MT remains off when it has a threshold voltage higher than the read voltage, and it turns on when it has a threshold voltage lower than the read voltage. When the string STR includes a selected cell transistor MT which is on (on cell-transistor), a current path is formed between the cell source line CELSRC and a bit line BL. In contrast, when the string STR includes a selected cell transistor MT which is off (off cell-transistor), a current path is not formed between the cell source line CELSRC and a bit line BL.

From the time t1, the controller 16 sets the potential of the node VLSA to the potential VDDSA. Moreover, the controller 16 sets the signal BLV to a potential Vblv from the time t1. The potential Vblv is higher than the potential VSS, and has a magnitude to allow the transistor 39 transfer the potential VDDSA. The application of the potential Vblv raises the potential of the node BLI toward the potential VDDSA from the time t1.

Moreover, the BLS controller 161 sets the signal BLS to a potential Vbls from the time t1. The potential Vbls is equal to the sum of the higher threshold voltage Vthra and the potential VDDSA. The transistor 31 can transfer the potential VDDSA while it is receiving the potential Vbls at its gate. For this reason, from the time t1, the potential of the node BLI is transferred to the bit line BL, and therefore the bit line BL has substantially the same potential as the node BLI.

Furthermore, the controller 16 applies the potential VDDSA to the node CELSRC from the time t1. For the case of the string STR including an on-cell, a current flows into the bit line BL from the node CELSRC. In contrast, for the case of the string STR including an off-cell, a current does not flow into the bit line BL from the node CELSRC.

Moreover, the controller 16 applies a potential Vsasrc to a node SASRC from the time t1. The potential Vsasrc is smaller than the potential. VDDSA, and is smaller than the potential of the bit line BL coupled to a string STR including an off-cell from the time t2, which will be described.

From the time t2, the controller 16 sets the signal BLC to a potential Vblc. The potential Vblc has a magnitude which allows the transistor 32 to transfer the potential VDDSA. For this reason, the potentials of the-nodes N1 and BLI are substantially the same, and the transistor 34 is in the state where it is diode-coupled.

Moreover, the controller 16 sets a signal BLV to a potential VSS from the time t2. As a result, the transistor 39 turns off, the bit line BL and the node BLI are uncoupled from the node VLSA, and the charging of the bit line BL and the node BLI from the node VLSA stops. Along with this, the potential of the node VLSA may be brought back to the potential VSS.

With the electrical uncoupling of the bit line BL and the node BLI from the node VLSA, the potentials of the bit line BL and the node BLI fall. For the case of the bit line BL coupled to a string STR including an on-cell, a current flows into the bit line BL through that string STR, and therefore the potentials of the bit line BL and the node BLI do not fall greatly (solid line). In contrast, for the case of the bit line BL coupled to a string STR including an off-cell, a current does not flow into the bit line BL through that string STR, and therefore the potentials of the bit line BL and the node BLI fall greatly (dashed line).

After a time passes from the time t2, the current which flows into the node SASRC through the diode-coupled transistor 34 from the bit line BL stabilizes, and potentials of the bit line BL and the nodes BLI and N1 stabilize. The potential of the node N1 stabilizes at a magnitude based on whether the string STR includes an on-cell or an off-cell.

The controller 16 and the BLS controller 161 set the signals BLC and BLS to the potential VSS from a time t3, which comes after the potentials of the bit line BL and the nodes BLI and N1 stabilize. As a result, the node BLI electrically floats and maintains the potential just before the time t3, and the node N1 electrically floats and maintains the potential just before the time t3. The potentials of the nodes BLI and N1 are maintained, and therefore the transistor 34 remains diode-coupled even after the time t3.

The controller 16 sets the signal XXL to a potential Vxxl from a time t4. The potential Vxxl has a magnitude to allow the transistor 35 to transfer a to-be-transferred potential when applied to the gate of the transistor 35, and has the same magnitude as the potential Vblc, for example. The application of the potential Vxxl switches the node N1 from a state where it electrically floats to a state where it is electrically coupled to the node SEN. AS a result of the node N1 coupled to the node SEN, a current flows into the node SASRC from the node SEN. At this time, the quantity of a fall of the potential of the node SEN varies based on the potential of the node N1, and based on the quantity the potential of the node SEN thereafter also varies. With this potential of the node SEN being sensed, the data stored in the selected cell transistor MT is determined.

According to the memory device 1 of the second embodiment, the same advantages as the first embodiment can be obtained.

In the sense amplifier unit 152, the signal BLS is brought back to the potential VSS during a read. The fall of the signal BLS produces noise in the potential of the node BLI via coupling. The higher the potential Vbls, the larger the difference between the potential Vbls and the potential VSS, and in turn the larger the difference, the larger the decrease at the falling back from the potential Vbls to the potential VSS and therefore the less coupling noise there is in the potential of the node BLI.

Moreover, there is a restriction that the turning off of the transistors 31 and 32 for uncoupling the nodes BLI and N1 from the bit line BL to make them electrically float as described above should occur substantially simultaneously. Otherwise, the potentials of the nodes BLI and N1 are different before and after uncoupling of the nodes BLI and N1. This can prevent a normal operation of the sense amplifier unit 152, and by extension a correct read of data of the selected cell transistor MT. With such restriction, a large potential Vbls may take a longer time to decrease to the potential VSS, and prevent simultaneous turning off of the transistors 31 and 32.

According to the second embodiment, for the same reasons as described in the first embodiment, the potentials applied to the gates of the transistors 31a and 31b in order to allow the transistors 31a and 31b to transfer the potential VDDSA is the potential Vbls. (=sum of the potential VDDSA and the higher threshold voltage Vthra), and has a necessary minimum magnitude. This can suppress the coupling noise in the potential of the node BLI when the signal BLS is decreased from the potential Vbls to the potential Vss, and suppress a time for the signal BLS to decrease from the potential Vbls to the potential Vss. This enables a correct operation of the sense amplifier unit 152, and in turn allows for a read of the data of the selected cell transistor MT with a higher reliability.

### Third Embodiment

The third embodiment differs from the first embodiment in details of the BLS controller 161. In the third embodiment, the sense amplifier 15 may have either of the sense amplifier unit 151 of the first embodiment and the sense amplifier unit 152 of the second embodiment.

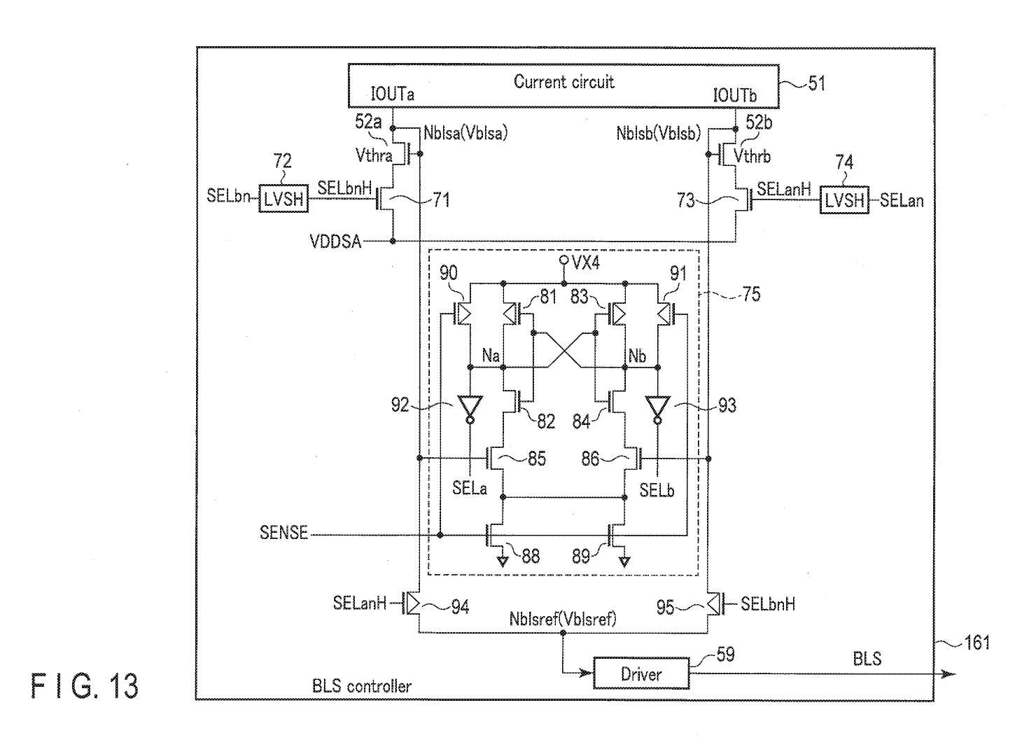

FIG. 13 illustrates components and connections of a BLS controller 161 of the memory device 1 of the third embodiment. The BLS controller 161 includes a current circuit 51, transistors 52a and 52b, n-type MOSFETs 71 and 73, a voltage differential amplifier 75, p-type MOSFETs 94 and 95, and a driver 59.

An output IOUTa (node Nblsa) is coupled to one end of the transistor 71 via the transistor 52a, and coupled to a gate of the transistor 52a. The other end of the transistor 71 is coupled to a node of the power potential VDDSA. The transistor 71 receives an output SELbnH of the level shifter 72 at its gate. The level shifter 72 receives a signal SELbn, which has the inverted logic of a digital signal SELb, and outputs a signal SELbnH, which is a potential-boosted version of the signal SELbn. The signal SELb is a signal on a particular node in the BLS controller 161.

An output IOUTb (node Nblsb) is coupled to one end of the transistor 73 via the transistor 52b, and coupled to a gate of the transistor 52b. The other end of the transistor 73 is coupled to the node of the potential VDDSA. The transistor 73 receives an output SELanH of the level shifter 74 at its gate. The level shifter 74 receives a signal SELan, which has the inverted logic of a digital signal SELa, and outputs a signal SELanH, which is a potential-boosted version of the signal SELan. The signal SELa is a signal on a particular node in the BLS controller 161.

The nodes Nblsa and Nblsb are coupled to the voltage differential amplifier 75, which is a gate-input type. The amplifier 75 amplifies the difference between the inputs Nblsa and Nblsb to a difference between a power potential VX4 and the ground potential VSS. The amplifier 75 outputs the digital signal SELa of the high level when the potential of the node Nblsa is higher than the potential of the node Nblsb. In contrast, the amplifier 75 outputs the digital signal SELb of the high level when the potential of the node Nblsb is higher than the potential of the node Nblsa.

For such an operation, the amplifier 75 includes p-type MOSFETs 81, 83, 90, and 91, n-type MOSFETs 82, 84, 85, 86, 88, and 89, and inverter circuits 92 and 93, for example.

Each of the set of the transistors 81 and 82 and the set of the transistors 83 and 84 makes an inverter, and the two inverters are so-called cross-coupled. Specifically, one end of the transistor 81 and one end of the transistor 82 are coupled to a node Na, and one end of the transistor 83 and one end of the transistor 84 are coupled to a node Nb. The other end of the transistor 81 and the other end of the transistor 83 are coupled to the node of a potential VX4. Gates of the transistors 81 and 82 are coupled to the node Nb, and gates of the transistors 83 and 84 are coupled to the node Na.

The other end of the transistor 82 is coupled to one end of the transistor 85, and the other end of the transistor 84 is coupled to one end of the transistor 86. The other end of the transistor 85 and the other end of the transistor 86 are coupled. The other end of the transistor 85 as further grounded via the transistor 88, and the other end of the transistor 86 is further grounded via the transistor 89. The transistor 85 is coupled to the node Nblsa at its gate, and the transistor 86 is coupled to the node Nblsb at its gate. The transistors 88 and 89 receive a digital signal SENSE from the controller 16 at their gates.

The node Na is also coupled to the node of the potential VX4 via the transistor 90, and the node Nb is also coupled to the node of the potential VX4 via the transistor 91. The transistors 90 and 91 receive the signal SENSE at their gates.

The node Na is further coupled to an input of the inverter circuit 92. An output of the inverter circuit 92 serves as the signal SELa. The node Nb is further coupled to an input of the inverter circuit 93. An output of the inverter circuit 93 serves as the signal SELb.

The node Nblsa is further coupled to one end of the transistor 94, and the node Nblsb is further coupled to one end of the transistor 95. The other end of the transistor 94 and the other end of the transistor 95 are coupled to a node Nblsref. The node Nblsref is coupled to an input of the driver 59. The transistor 94 receives an output SELanH of the level shifter 74, and the transistor 95 receives an output SELbnH of the level shifter 72.

The BLS controller 161 may include additional components. For example, a p-type MOSFET which receives the signal SENSE at its gate is provided between the gate of the transistor 82 and the gate of the transistor 84. Moreover, an n-type MOSFET is provided between the node at which the transistors 82 and 85 are coupled and the node of the potential VSS. This MOSFET receives at its gate a signal which becomes high if the threshold voltages of the transistors 31a and 31b are the same (and as a result the threshold voltages of the transistors 52a and 52b are the same).

The BLS controller 161 operates as described in the following. The signal SENSE is at the low level before a start of the operation. For this reason, the nodes Na and Nb are precharged to have the potential VX4 via the transistors 90 and 91, and therefore the transistors 81 and 83 are OFF and the transistors 82 and 84 are ON.

At the start of the operation, the potential Vblsa of the node Nblsa and the potential Vblsb of the node Nblsb are at the potential VSS. For this reason, the transistors 85 and 86 are OFF, and the inverter circuit of the transistors 81 and 82 and the inverter circuit of the transistors 83 and 84 are in a floating state, and are in an indefinite state. Moreover, the transistors 71 and 73 are ON.

When the BLS controller 161 receives an asserted signal SENSE (or, of the high level), it starts to operate. The high-level signal SENSE stops the precharging of the nodes Na and Nb with the transistors 90 and 91, and turns on the transistors 88 and 89.

The start of the operation triggers output of currents from the outputs IOUTa and IOUTb of the current circuit 51. These currents increase the potential Vblsa of the node Nblsa and the potential Vblsb of the node Nblsb. The increased potential Vblsa is equal to the sum of the potential VDDSA and the threshold voltage Vthra of the transistors 52a. The increased potential Vblsb is equal to the sum of the potential VDDSA and the threshold voltage Vthrb of the transistors 52b. The potentials Vblsa and Vblsb are different because respective magnitudes of respective threshold voltages Vthra and Vthrb of the transistors 52a and 52b are different. The following description is based on an example with the potential Vblsa being higher than potential Vblsb as in the first embodiment.

The transistor 85 which receives at its gate the potential Vblsa, which is higher, turns on more strongly than the transistor 86. For this reason, the node Na is more strongly pulled down to the potential VSS than the node Nb, and turns on the transistor 83 and turns off the transistor 84. This sets the node Nb to the potential VX4. The node Nb of potential VX4 maintains the transistor 81 off and turns on the transistor 82. This sets the node Na to the potential VSS. Thus, the states of the inverter circuit of the transistors 81 and 82 and the inverter circuit of the transistors 83 and 84 are settled, which in turn sets the nodes Na and Nb to the low level and high level, respectively. Therefore, the signals SELa and SELb are set to the high level and low level, respectively.

The high-level signal SELa turns off the transistor 73 and turns on the transistor 94. Moreover, the low-level signal SELb turns on the transistor 71 and turns off the transistor. This results in only the node Nblsa among the nodes Nblsa and Nblsb being coupled to the node Nblsref via the transistor 94, and the node Nblsb not being coupled to the node Nblsref. In other words, the potential Vblsa is selected among the potentials Vblsa and Vblsb, and supplied to the driver 59. In this way, the potential Vblsa of the node Nblsref is output as the signal BLS from the driver 59.

When the threshold voltage Vthb of the transistor 31b is higher than the threshold voltage Vtha of the transistor 31a, the signal SELb becomes high, which turns off the transistor 71 and turns on the transistor 95. Moreover, the signal SELa becomes low, which turns on the transistor 73 and turns off the transistor 94. As a result, the potential Vblsb is selected among the potentials Vblsa and Vblsb, and supplied to the driver 59.

Also with the second embodiment., the higher one of the potentials Vblsa and Vblsb is exclusively selected, and is output as the signal BLS. The potential Vblsa is the sum of the potential VDDSA and the threshold voltage Vtha of the transistors 52a, and the potential Vblsb is the sum of potential VDDSA and the threshold voltage Vthb of the transistors 52b. For this reason, the sum of the higher one of respective threshold voltages Vtha and Vthb of the transistors 31a and 31b and the potential VDDSA is applied to the gates of the transistors 31a and 31b as in the first and second embodiments. This can produce the same advantages as the first or second embodiment.

### Fourth Embodiment

The fourth embodiment differs from the first embodiment in the details of the BLS controller 161. In the fourth embodiment, the sense amplifier unit 15 may have either of the sense amplifier unit 151 of the first embodiment and the sense amplifier unit 152 of the second embodiment.

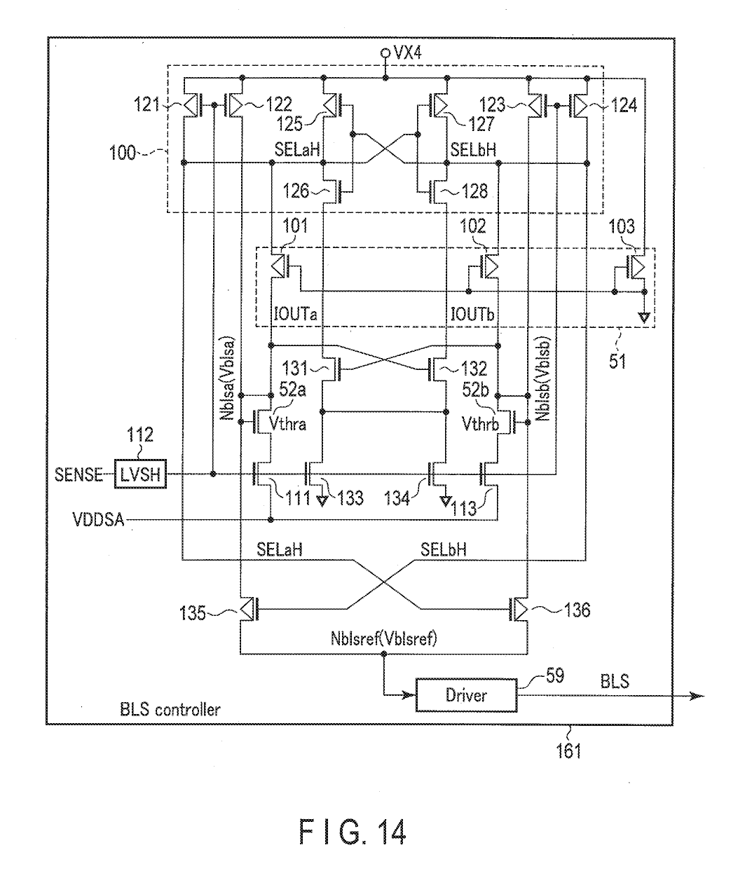

FIG. 14 illustrates components and connections of a BLS controller 161 of the memory device 1 of the fourth embodiment. The BLS controller 161 includes a current circuit 51, a voltage differential amplifier 100, transistors 52a and 52b, n-type MOS transistors 111, 113, 131, 132, 133, and 134, p-type MOS transistors 135 and 136, and a driver 59.

The current circuit 51 includes p-type MOS transistors 101 to 103, for example. One end of the transistor 101 is coupled to a node of a signal SELaH, and the other end serves as an output. IOUTa of the current circuit 51. One end of the transistor 102 is coupled to a node of a signal SELbH, and the other end serves as an output IOUTb the current circuit 51. Gates of the transistors 101 and 102 are coupled to a mate and one end of the transistor 103 and a node of a ground potential VSS. The other end of the transistor 103 is coupled to a node of a power potential VX4.

The output IOUTa (node Nblsa) is coupled to one end of the transistor 111 via the transistor 52a and a gate of the transistor 52a. The other end of the transistor 111 is coupled to the node of the power potential VDDSA. The transistor 111 receives an output of the level shifter 112 at its gate. The level shifter 112 outputs a potential-increased version of a digital signal SENSE.

The output IOUTb (node Nblsb) is coupled to one end of the transistor 113 via the transistor 52b and a gate of the transistor 52b. The other end of the transistor 113 is coupled to the node of the potential VDDSA. The transistor 113 receives the output of the level shifter 112 at its gate.

The amplifier 100 pulls up the larger one of the potentials of signals SELaH and SELbH to the potential VX4, pulls down the smaller one to the potential VSS, and outputs digital signals SELaH and SELbH. For such an operation, the amplifier 100 includes p-type MOS transistors 121, 122, 123, 124, 125, and 127, and n-type MOS transistors 126 and 128, for example.

The node of the signal SELaH is coupled to the node of the potential VX4 via the transistor 121. The transistor 122 is coupled between the node of the potential VX4 and the node Nblsa. The transistors 121 and 122 receive the output of the level shifter 112 at their gates. The transistors 121 and 122 precharge the node of the signal SELaH and the node Nblsa, respectively.

The node of signal SELbH is coupled to the node of the potential VX4 via the transistor 124. The transistor 123 is coupled between the node of the potential VX4 and the node Nblsb. The transistors 123 and 124 receive the output of the level shifter 112 at their gates. The transistors 123 and 124 precharge the node of signal SELbH and the node Nblsb, respectively.

Each of the set of the transistors 125 and 126 and the set of the transistors 127 and 128 makes an inverter, and the two inverters are so-called cross-coupled. Specifically, one end of the transistor 125 and one end of the transistor 126 are coupled to the node of the signal SELaH, and one end of the transistor 127 and one end of the transistor 128 are coupled to the node of the signal SELbH. The other end of the transistor 125 and the other end of the, transistor 127 are coupled to the node of the potential VX4. Gates of the transistors 125 and 126 are coupled to the node of the signal SELbH, and gates of the transistors 127 and 128 are coupled to the node of the signal SELaH.

The other end of the transistor 126 is coupled to one end of the transistor 131, and the other end of the transistor 128 is coupled to one end of the transistor 132. The other end of the transistor 131 is coupled to the node of the potential VSS via the transistor 133, and the other end of the transistor 132 is coupled to the node of the potential VSS via the transistor 134. The transistors 133 and 134 receive the output of the level shifter 112 at their gates.

The node Nblsa is further coupled to one end of the transistor 135, and the node Nblsb is further coupled to one end of the transistor 136. The other end of the transistor 135 and the other end of the transistor 136 are coupled to a Node Nblsref. The node Nblsref is coupled to an input of the driver 59. The transistor 135 is coupled to the node of the signal SELbH at its gate, and the transistor 136 is coupled to the node of the signal SELaH at its gate.

The BLS controller 161 may include additional components. For example, a p-type MOSFET which receives the output of the level shifter 112 at its gate is provided between the gate of the transistor 126 and the gate of the transistor 128. Moreover, an n--type MOSFET is provided between the node of the signal SELaH and the node of the potential VSS. This MOSFET receives at its gate a signal which becomes high if the threshold voltages of the transistors 31a and 31b are the same (and as a result the threshold voltages of the transistors 52a and 52b are the same).

The BLS controller 161 operates as described in the following. The signal SENSE is at the low level before a start of an operation. For this reason, the transistors 121, 122, 123, and 124 are ON, and the nodes of the signals SELaH and SELbH and the nodes Nblsa and Nblsb are precharged to have the potential VX4. For this reason, the transistors 125 and 127 are OFF and the transistors 126, 128, 131, and 132 are ON.

The BLS controller 161 starts to operate when it receives an asserted signal SENSE (or, of the high level). The high-level signal SENSE stops the precharging of the nodes of the signals SELaH and SELbH and the nodes Nblsa and Nblsb with the transistors 121, 122, 123, and 124, and turns on the transistors 111, 113, 133, and 134.

The start of the operation triggers output of currents from the outputs IOUTa and IOUTb of the current circuit 51. These currents set the potential Vblsa to the sum of the potential VDDSA and the threshold voltage Vthra of the transistors 52a, and set the potential Vblsb to the sum of the potential VDDSA and the threshold voltage Vthrb of the transistors 52b. The potentials Vblsa and Vblsb are different because respective magnitudes of the threshold voltages Vthra and Vthrb of respective transistors 52a and 52b are different. The following description is based on an example with the potential Vblsa being higher than potential Vblsb as in the first embodiment.

The transistor 132 which receives at its gate the potential Vblsa, which is higher, turns on more strongly than the trans 131. For this reason, the node of the signal SELbH is pulled down to the potential VSS more strongly than the node of the signal SELaH, and turns on the transistor 125 and turns off the transistor 126. This sets the node of the signal SELaH to the potential VX4. The node of the signal SELaH of the potential VX4 maintains the transistor 127 off and maintains the transistor 128 on. This sets the signal SELbH to the potential VSS. Thus, the states of the inverter circuit of the transistors 125 and 126 and the inverter circuit of the transistors 127 and 128 are settled, which in turn sets the signals SELaH and SELbH to the potentials VX4 and VSS, respectively.

The signal SELbH of the potential VSS turns on the transistor 135 and maintains the transistor 136 off. This results in only the node Nblsa among the nodes Nblsa and Nblsb being coupled t the Node Nblsref via the transistor 135, and the node Nblsb not being coupled to the node Nblsref. In other words, the potential Vblsa is selected among the potentials Vblsa and Vblsb, and supplied to the driver 59. In this way, the potential Vblsa of the node Nblsb is output as the signal BLS from the driver 59.

When the threshold voltage Vthb of the transistor 31b is higher than the threshold voltage Vtha of the transistor 31a, the signal SELaH of the potential VSS turns on the transistor 136 and maintains the transistor 135 off. As a result, the potential Vblsb is selected among the potentials Vblsa and Vblsb, and supplied to the driver 59.

Also with the third embodiment, the higher one of the potentials Vblsa and. Vblsb is exclusively selected, and is output as the signal BLS. The potential Vblsa is the sum of the potential VDDSA and the threshold voltage Vtha of the transistors 52a, and the potential Vblsb is the sum of the potential VDDSA and the threshold voltage Vthb of the transistors 52b. The sum of the higher one of respective threshold voltages Vtha and Vthb of the transistors 31a and 31b and the potential VDDSA is applied to the gates of the transistors 31a and 31b. This can produce the same advantages as the first or second embodiment.

For a case of the memory device 1 being a NAND type flash memory, the following operation and configuration can be used.

In a multi-level read operation, threshold voltages may be A-level, B-level, and C-level from the smallest one to the largest one. The voltage applied to a word line selected for the A-level read operation is, for example, between 0V and 0.55V. The voltage is not limited thereto, and may be any one of between 0.1V and 0.24V, between 0.21V and 0.31V, between 0.31V and 0.4V, between 0.4V to 0.5V, and between 0.5V and 0.55V.

The voltage applied to a word line selected for the B-level read operation is, for example, between 1.5V and 2.3V, The voltage is not limited thereto, and may be any one of between 1.65 V and 1.8 V, between 1.8V and 1.95V, between 1.95V and 2.1V, and between 2.1V and 2.3V.

The voltage applied to a word line selected for the C-level read operation is, for example, 3.0V and 4.0V. The voltage is not limited thereto, and may be any one of between 3.0V and 3.2V, between 3.2V and 3.4V, between 3.4V and 3.5V, between 3.5V and 3.6V, and between 3.6 V and 4.0V.

The time for the read operation (tR) may be, for example, between 25 μs and 38 μs, between 38 μs and 70 μs, or between 70 μs to 80 μs.

A write operation includes a program operation and a verification operation. In the write operation, the voltage first applied to a word line selected for the program operation is, for example, between 13.7V and 14.3V. The voltage is not limited thereto, and may be either one of between 13.7V and 14.0V and between 14.0V and 14.6V.

The voltage first applied to a selected word line in a writing into an odd word line may differ from, the voltage first applied to a selected word line in a writing into an even word line. When an Incremental Step Pulse Program (ISPP) is used for the program operation, the voltage may be stepped up by approximately 0.5V, for example.

The voltage applied to unselected word lines during a write operation is, for example, between 6.0V and 7.3V. The voltage is not limited thereto, and may be, for example, between 7.3V and 8.4V or may be 6.0V or less. The pass voltage to be applied may be changed depending on whether an unselected word line is an odd word line or an even word line.

The time for the write operation (tProg) may be, for example, between 1700 μs and 1800 μs, between 1800 μs and 1900 μs, or between 1900 μs to 2000 μs.

In the erase operation, the voltage first applied to a well, which is formed in a top area of the semiconductor substrate and above which the memory cells are arranged, is, for example, between 12V and 13.6V. The voltage is not limited thereto, and may be, for example, between 13.6V and 14.8V, between 14.8V and 19.0V, between 19.0V and 19.8V, or between 19.8V and 21V.

The time for the erase operation (tErase) may be, for example, between 3000 μs and 4000 μs, between 4000 μs and 5000 μs, or between 4000 μs and 9000 μs.

A memory cell may have the following structure. The memory cell includes a charge accumulation layer disposed on the semiconductor substrate (silicon substrate) via a tunnel insulation film of a thickness of 4 nm to 10 nm. The charge accumulation layer may have a stacked structure including an insulation film of silicon nitride (SiN) film or silicon oxinitride (SiON) film of a thickness of 2 nm to 3 nm and polysilicon (poly-Si) of a thickness of 3 nm to 8 nm. The polysilicon may include a metal such as ruthenium (Ru). The memory cell includes an insulation film on the charge accumulation layer. This insulation film includes, for example, a silicon oxide film of a thickness of 4 nm to 10 nm between a lower high-k film of a thickness of 3 nm to 10 nm and an upper high-k film of a thickness of 3 nm to 10 nm. The high-k film includes, for example, hafnium oxide (HfO). The silicon oxide film can be greater in thickness than the high-k film. A control electrode of a thickness of 30 nm to 70 nm is formed on the insulation film with a material for work function adjustment of a thickness of 3 nm to 10 nm interposed therebetween. Here, the material for work function adjustment includes a metal-oxide film such as tantalum oxide (TaO) or a metal-nitride film such as tantalum nitride (TaN). For example, tungsten (W) can be used for the control electrode.

An air gap can be formed between the memory cells.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may he made without departing from the spirit of the inventions. The accompanying claims and their equivalents are intended to cover such forms or modifications as would fall within the scope and spirit of the inventions.

What is claimed is:

1. A semiconductor memory device comprising:
a first transistor including a first end coupled to a first node, a second end, and a gate coupled to the second end;
a second transistor including a third end coupled to the first node, a fourth end, and a gate coupled to the fourth end;
a third transistor between a first bit line and a second node in a first sense amplifier; and
a selector configured to supply a gate of the third transistor with one of a potential of the second end and a potential of the fourth end.

2. The device according to claim 1, wherein:
the selector is configured to supply the gate of the third transistor with a first potential of the second end when the first potential is larger than a second potential of the fourth end.

3. The device according to claim 2, wherein:
the selector is configured to supply the gate of the third transistor with the second potential when the first potential is smaller than the second potential.

4. The device according to claim 1, wherein:
the sense amplifier includes:
a fourth transistor between the third transistor and a third node;
a fifth transistor between the third node and a fourth node;
a sixth transistor between the third node and a fifth node; and
a seventh transistor between the fourth node and the fifth node.

5. The device according to claim 1, wherein:
the first sense amplifier includes:
a fourth transistor between the third transistor and a third node;
a fifth transistor between the third node and a fourth node, the fifth transistor including a gate coupled to the second node; and
a sixth transistor between the third node and a fifth node.

6. The device according to claim 5, further comprising:
a controller configured to:
supply a first potential to a gate of the fourth transistor while the selector is supplying the gate of the third transistor with one of the potential of the second end and the potential of the fourth end, and
supply a second potential to a gate of the sixth transistor after the supply of one of the potential of the second end and the potential of the fourth end to the gate of the third transistor and the supply of the first potential to the gate of the fourth transistor are finished.

7. The device according to claim 1, wherein:
each of the first transistor and the second transistor includes a source/drain area of a first conductivity type,
the semiconductor memory device further comprises a first impurity region of a second conductivity type below the source/drain areas of the first and second transistors, and
a distance between the first impurity region and the gate of the first transistor is shorter than a distance between the first impurity region and the gate of the second transistor.

8. The device according to claim 7, wherein:
the semiconductor memory device further comprises a seventh transistor between a second bit line and a node of a second sense amplifier,
each of the third transistor and the seventh transistor includes a source/drain area of the first conductivity type,
the semiconductor memory device further comprises a second impurity region of the second conductivity type below the source/drain areas of the third and seventh transistors, and
a distance between the second impurity region and the gate of the third transistor is shorter than a distance between the second impurity region and the gate of the seventh transistor.

9. The device according to claim 8, wherein:
the first, second, third, and seventh transistors are provided on a first surface of a substrate,
a shape of the first transistor along the first surface is substantially the same as a shape of the third transistor along the first surface.

10. The device according to claim 9, wherein:
a shape of the second transistor along the first surface is substantially the same as a shape of the seventh transistor along the first surface.

11. The device according to claim 10, wherein
a shape of the first impurity region along the first surface is substantially the same as a shape of the second impurity region along the first surface, and
mutual positional relationships among the gate of the first transistor, the gate of the second transistor, and the second impurity region are substantially the same as mutual positional relationships among the gate of the third transistor, the gate of the seventh transistor, and the first impurity region, respectively.

12. The device according to claim 1, wherein:
the selector includes:
a fourth transistor between the second end and the gate of the third transistor;
a fifth transistor between the fourth end and the gate of the third transistor; and
a controller configured to supply a gate of the fourth transistor with a first signal and a gate of the fifth transistor with a second signal complementary to the first, signal when a first potential of the second end is larger than a second potential of the fourth end.

13. The device according to claim 12, wherein:
the controller includes:
an operational amplifier including a first input coupled to the second end and a second input coupled to the fourth end;
an inverter circuit including an input coupled to an output of the operational amplifier; and
a level shifter including an input coupled to an output of the inverter circuit, a first output coupled to the gate of the fourth transistor, and a second output coupled to the gate of the fifth transistor.

14. The device according to claim 12, wherein:
the controller includes:
a first inverter circuit including a first input and a first output, the first output being coupled to the gate of the fourth transistor;
a second inverter circuit including a second input and a second output, the second input being coupled to the first output, the second output being coupled to the, first input and the gate of the fifth transistor;
a sixth transistor coupled to the first inverter circuit and including a gate coupled to the second end; and
a seventh transistor coupled to the second inverter circuit and including a gate coupled to the fourth end.

15. The device according to claim 12, wherein:
the controller includes:
a first inverter circuit including a first input and a first output, the first input being coupled to the fourth end, and the first output being coupled to the second end;
a second inverter circuit including a second input and a second output, the second input coupled to the first output, and the second output being coupled to the first input;
a sixth transistor coupled to the first inverter circuit and including a gate coupled to the fourth end; and
a seventh transistor coupled to the second inverter circuit and including a gate coupled to the second end.
